(19) United States
(12) Patent Application Publication
(10) Pub. No.: US 2026/0339220 A1
(43) Pub. Date: Oct. 29, 2026

(54) SUBSTRATE SUPPORT QUALIFICATION

(71) Applicant: ASML NETHERLANDS B.V., Veldhoven (NL)

(72) Inventors: Christianus Wilhelmus Johannes BERENDSEN, Eindhoven (NL); Maarten Marinus VAN OENE, Waalwijk (NL); Cornclius Maria ROPS, Waalre (NL); Johannes Andreas Maria AMMERLAAN, Eindhoven (NL); Giovanni Luca GATTOBIGIO, Eindhoven (NL)

(73) Assignee: ASML NETHERLANDS B.V., Veldhoven (NL)

(21) Appl. No.: 19/114,493

(22) PCT Filed: Sep. 12, 2023
(86) PCT No.: PCT/EP2023/074956

§ 371 Date: Mar. 24, 2025

(30) Foreign Application Priority Data
Oct. 12, 2022 (EP) 22201001.9

(51) Int. Cl. G03F 7/00

(52) U.S. Cl. CPC G03F 7/7085; G03F 7/70341; G03F 7/70875

(57) ABSTRACT

A stand-alone qualification system for determining at least one operating characteristic of a fluid extraction system of a substrate support, the qualification system including: an extraction support system configured to support a two-phase fluid extraction by the fluid extraction system; and a measurement system configured to determine at least one operating characteristic of the fluid extraction system in dependence on the two-phase fluid extraction.

### CROSS-REFERENCE TO RELATED APPLICATIONS

This application claims priority of EP Application Serial No. 22201001.9 which was filed on 12 October 2022 and which is incorporated herein in its entirety by reference.

### FIELD

The present invention relates to the qualification of the fluid extraction system of a substrate support. Embodiments include a stand-alone tool for determining the performance of the fluid extraction system of a substrate support. Embodiments also include determining the performance of the fluid extraction system of a substrate support when the substrate support is operated within a lithographic apparatus.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer). Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction.

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm.

Further improvements in the resolution of smaller features may be achieved by providing an immersion fluid having a relatively high refractive index, such as water, on the substrate during exposure. The effect of the immersion fluid is to enable imaging of smaller features since the exposure radiation will have a shorter wavelength in the fluid than in gas. The effect of the immersion fluid may also be regarded as increasing the effective numerical aperture (NA) of the system and also increasing the depth of focus.

The immersion fluid may be confined to a localized area between the projection system of the lithographic apparatus and the substrate by a fluid handling structure.

### SUMMARY

In an immersion semiconductor manufacturing process, immersion fluid may be continuously supplied to the illuminated region of the substrate. The substrate is supported by a substrate support. The substrate support comprises a fluid extraction system for extracting the supplied immersion fluid.

The reliability of the manufacturing process is dependent on the performance of the fluid extraction system. Incorrect operation of the fluid extraction system may result in bubbles forming in the immersion fluid. The presence of bubbles increases the risk of manufacturing defects occurring. There is a general need to improve on known techniques for qualifying a fluid extraction system so as to determine if the fluid extraction system is operating within its performance specification.

According to a first aspect of the invention, there is provided a stand-alone qualification system for determining at least one operating characteristic of a fluid extraction system of a substrate support, the qualification system comprising: an extraction support system configured to support a two-phase fluid extraction by the fluid extraction system; and a measurement system configured to determine at least one operating characteristic of the fluid extraction system in dependence on the two-phase fluid extraction.

According to a second aspect of the invention, there is provided a substrate for use in the determination of at least one operating characteristic of a fluid extraction system of a substrate support, the substrate comprising: one or more channels on a major surface of the substrate for containing a deposited liquid on the major surface of the substrate; wherein each channel has an end at an edge of the substrate.

According to a third aspect of the invention, there is provided an arrangement comprising: the qualification system according to the first aspect; and a substrate according to the second aspect.

According to a fourth aspect of the invention, there is provided an arrangement comprising: an immersion lithographic apparatus; and a substrate according to the second aspect.

According to a fifth aspect of the invention, there is provided a method of determining at least one operating characteristic of a fluid extraction system of a substrate support, the method comprising: depositing liquid onto a substrate; extracting the liquid from the substrate in a two-phase fluid flow; and determining at least one operating characteristic of the fluid extraction system in dependence on the two-phase fluid extraction.

Further embodiments, features and advantages of the present invention, as well as the structure and operation of the various embodiments, features and advantages of the present invention are described in detail below with reference to the accompanying drawings.

### DESCRIPTION OF THE DRAWINGS

Embodiments of the invention will now be described, by way of example only, with reference to the accompanying schematic drawings, in which corresponding reference symbols indicate corresponding parts, and in which:

FIG. 1 depicts a schematic overview of the lithographic apparatus;

FIGS. 2 and 3 depict, in cross-section, two different versions of a fluid handling system for use in a lithographic projection apparatus;

FIG. 4 depicts, in cross-section, a substrate support not in accordance with the present invention;

FIG. 5 schematically shows a qualification system of a fluid extraction system of a substrate support according to a first embodiment;

FIG. 6 schematically shows a test substrate according to an embodiment;

FIGS. 7A and 7B schematically show different implementations of a liquid confinement channel according to embodiments;

FIG. 8 shows a hypothetical measurement result of the power consumption of a heater 510 during the qualification process;

FIG. 9 schematically shows part of a lithographic apparatus in a second embodiment; and

FIG. 10 schematically shows a test substrate according to an embodiment.

The features shown in the Figures are not necessarily to scale, and the size and/or arrangement depicted is not limiting. It will be understood that the Figures include optional features which may not be essential to the invention. Furthermore, not all of the features of the apparatus are depicted in each of the figures, and the Figures may only show some of the components relevant for describing a particular feature.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

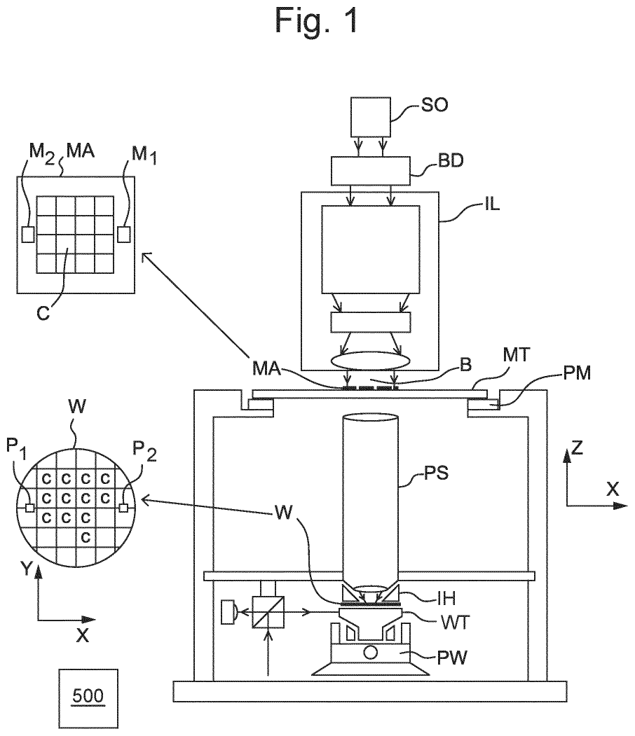

FIG. 1 schematically depicts a lithographic apparatus. The lithographic apparatus includes an illumination system (also referred to as illuminator) IL configured to condition a radiation beam B (e.g., UV radiation or DUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a substrate table) WT constructed to hold a substrate (e.g., a resist coated wafer) W and connected to a second positioner PW configured to accurately position the substrate support WT in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives the radiation beam B from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross-section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus is of a type wherein at least a portion of the substrate W may be covered by an immersion liquid having a relatively high refractive index, e.g., water, so as to fill an immersion space 11 between the projection system PS and the substrate W—which is also referred to as immersion lithography. More information on immersion techniques is given in U.S. Pat. No. 6,952,253, which is incorporated herein by reference.

The lithographic apparatus may be of a type having two or more substrate supports WT (also named “dual stage”). In such a “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus may comprise a measurement stage (not depicted in figures). The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify the invention, a Cartesian coordinate system is used. The Cartesian coordinate system has three axis, i.e., an x-axis, a y-axis and a z-axis. Each of the three axis is orthogonal to the other two axis. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

Immersion techniques have been introduced into lithographic systems to enable improved resolution of smaller features. In an immersion lithographic apparatus, a liquid layer of immersion liquid having a relatively high refractive index is interposed in the immersion space 11 between a projection system PS of the apparatus (through which the patterned beam is projected towards the substrate W) and the substrate W. The immersion liquid covers at least the part of the substrate W under a final element of the projection system PS. Thus, at least the portion of the substrate W undergoing exposure is immersed in the immersion liquid.

In commercial immersion lithography, the immersion liquid is water. Typically the water is distilled water of high purity, such as Ultra-Pure Water (UPW) which is commonly used in semiconductor fabrication plants. In an immersion system, the UPW is often purified and it may undergo additional treatment steps before supply to the immersion space 11 as immersion liquid. Other liquids with a high refractive index can be used besides water as the immersion liquid, for example: a hydrocarbon, such as a fluorohydrocarbon; and/or an aqueous solution. Further, other fluids besides liquid have been envisaged for use in immersion lithography.

In this specification, reference will be made in the description to localized immersion in which the immersion liquid is confined, in use, to the immersion space 11 between the final element and a surface facing the final element. The facing surface is a surface of substrate W or a surface of the supporting stage (or substrate support WT) that is co-planar with the surface of the substrate W. (Please note that reference in the following text to surface of the substrate W also refers in addition or in the alternative to the surface of the substrate support WT, unless expressly stated otherwise; and vice versa). A fluid handling structure IH present between the projection system PS and the substrate support WT is used to confine the immersion liquid to the immersion space 11. The immersion space 11 filled by the immersion liquid is smaller in plan than the top surface of the substrate W and the immersion space 11 remains substantially stationary relative to the projection system PS while the substrate W and substrate support WT move underneath.

Other immersion systems have been envisaged such as an unconfined immersion system (a so-called ‘All Wet’ immersion system) and a bath immersion system. In an unconfined immersion system, the immersion liquid covers more than the surface under the final element. The liquid outside the immersion space 11 is present as a thin liquid film. The liquid may cover the whole surface of the substrate W or even the substrate W and the substrate support WT co-planar with the substrate W. In a bath type system, the substrate W is fully immersed in a bath of immersion liquid.

The fluid handling structure IH is a structure which supplies the immersion liquid to the immersion space 11, removes the immersion liquid from the immersion space 11 and thereby confines the immersion liquid to the immersion space 11. It includes features which are a part of a fluid supply system. The arrangement disclosed in PCT patent application publication no. WO 99/49504 is an early fluid handling structure comprising pipes which either supply or recover the immersion liquid from the immersion space 11 and which operate depending on the relative motion of the stage beneath the projection system PS. In more recent designs, the fluid handling structure extends along at least a part of a boundary of the immersion space 11 between the final element of the projection system PS and the substrate support WT or substrate W, so as to in part define the immersion space 11.

The fluid handing structure IH may have a selection of different functions. Each function may be derived from a corresponding feature that enables the fluid handling structure IH to achieve that function. The fluid handling structure IH may be referred to by a number of different terms, each referring to a function, such as barrier member, seal member, fluid supply system, fluid removal system, liquid confinement structure, etc.

As a barrier member, the fluid handling structure IH is a barrier to the flow of the immersion liquid from the immersion space 11. As a liquid confinement structure, the structure confines the immersion liquid to the immersion space 11. As a seal member, sealing features of the fluid handling structure IH form a seal to confine the immersion liquid to the immersion space 11. The sealing features may include an additional gas flow from an opening in the surface of the seal member, such as a gas knife.

The fluid handling structure IH may supply immersion fluid and therefore be a fluid supply system.

The fluid handling structure IH may at least partly confine immersion fluid and thereby be a fluid confinement system.

The fluid handling structure IH may provide a barrier to immersion fluid and thereby be a barrier member, such as a fluid confinement structure.

The fluid handling structure IH may create or use a flow of gas, for example to help in controlling the flow and/or the position of the immersion fluid.

The flow of gas may form a seal to confine the immersion fluid so the fluid handling structure IH may be referred to as a seal member; such a seal member may be a fluid confinement structure.

Immersion liquid may be used as the immersion fluid. In that case the fluid handling structure IH may be a liquid handling system. In reference to the aforementioned description, reference in this paragraph to a feature defined with respect to fluid may be understood to include a feature defined with respect to liquid.

A lithographic apparatus has a projection system PS. During exposure of a substrate W, the projection system PS projects a beam of patterned radiation onto the substrate W. To reach the substrate W, the path of the radiation beam B passes from the projection system PS through the immersion liquid confined by the fluid handling structure IH between the projection system PS and the substrate W. The projection system PS has a lens element, the last in the path of the beam, which is in contact with the immersion liquid. This lens element which is in contact with the immersion liquid may be referred to as ‘the last lens element’ or “the final element”. The final element is at least partly surrounded by the fluid handling structure IH. The fluid handling structure IH may confine the immersion liquid under the final element and above the facing surface.

As depicted in FIG. 1, the lithographic apparatus comprises a controller 500. The controller 500 is configured to control the substrate table WT.

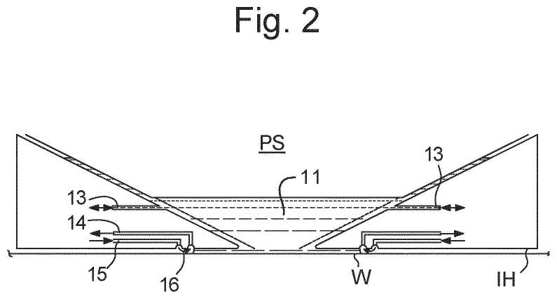

FIG. 2 schematically depicts a localized liquid supply system or fluid handling system. The liquid supply system is provided with a fluid handling structure IH (or liquid confinement structure), which extends along at least a part of a boundary of the space 11 between the final element of the projection system PS and the support table WT or substrate W. The fluid handling structure IH is substantially stationary relative to the projection system PS in the XY plane though there may be some relative movement in the Z direction (in the direction of the optical axis). In an example, a seal is formed between the fluid handling structure IH and the surface of the substrate W and may be a contactless seal such as a gas seal (such a system with a gas seal is disclosed in EP1,420,298) or liquid seal.

The fluid handling structure IH at least partly confines the immersion liquid in the space 11 between the final element of the projection system PS and the substrate W. The space 11 is at least partly formed by the fluid handling structure IH positioned below and surrounding the final element of the projection system PS. Immersion liquid is brought into the space 11 below the projection system PS and within the fluid handling structure IH by one of liquid openings 13. The immersion liquid may be removed by another of liquid openings 13. The immersion liquid may be brought into the space 11 through at least two liquid openings 13. Which of liquid openings 13 is used to supply the immersion liquid and optionally which is used to remove the immersion liquid may depend on the direction of motion of the support table WT.

The immersion liquid may be confined in the space 11 by a contactless seal such as a gas seal 16 formed by a gas which, during use, is formed between the bottom of the fluid handling structure IH and the surface of the substrate W. The gas in the gas seal 16 is provided under pressure via inlet 15 to the gap between the fluid handling structure IH and substrate W. The gas is extracted via outlet 14. The overpressure on the gas inlet 15, vacuum level on the outlet 14 and geometry of the gap are arranged so that there is a high-velocity gas flow inwardly that confines the immersion liquid. Such a system is disclosed in US 2004/0207824, which is hereby incorporated by reference in its entirety. In an example, the fluid handling structure IH does not have the gas seal 16.

FIG. 3 is a side cross-sectional view that depicts a further liquid supply system or fluid handling system. The arrangement illustrated in FIG. 3 and described below may be applied to the lithographic apparatus described above and illustrated in FIG. 1. The liquid supply system is provided with a fluid handling structure IH (or a liquid confinement structure), which extends along at least a part of a boundary of the space 11 between the final element of the projection system PS and the support table WT or substrate W.

The fluid handling structure IH at least partly confines the immersion liquid in the space 11 between the final element of the projection system PS and the substrate W. The space 11 is at least partly formed by the fluid handling structure IH positioned below and surrounding the final element of the projection system PS. In an example, the fluid handling structure IH comprises a main body member 53 and a porous member 33. The porous member 33 is plate shaped and has a plurality of holes (i.e., openings or pores). The porous member 33 may be a mesh plate wherein numerous small holes 84 are formed in a mesh. Such a system is disclosed in US 2010/0045949 A1, which is hereby incorporated by reference in its entirety.

The main body member 53 comprises supply ports 72, which are capable of supplying the immersion liquid to the space 11, and a recovery port 73, which is capable of recovering the immersion liquid from the space 11. The supply ports 72 are connected to a liquid supply apparatus 75 via passageways 74. The liquid supply apparatus 75 is capable of supplying the immersion liquid to the supply ports 72 through the corresponding passageway 74. The recovery port 73 is capable of recovering the immersion liquid from the space 11. The recovery port 73 is connected to a liquid recovery apparatus 80 via a passageway 79. The liquid recovery apparatus 80 recovers the immersion liquid recovered via the recovery port 73 through the passageway 29. The porous member 33 is disposed in the recovery port 73. Performing the liquid supply operation using the supply ports 72 and the liquid recovery operation using the porous member 33 forms the space 11 between the projection system PS and the fluid handling structure IH on one side and the substrate W on the other side.

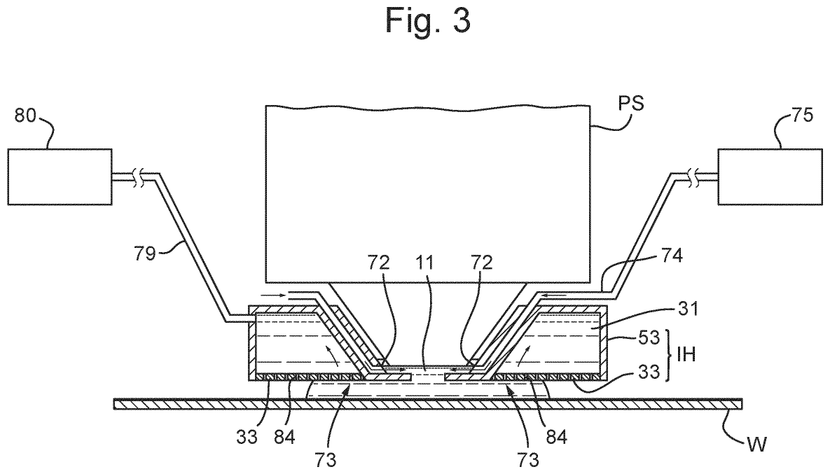

FIG. 4 illustrates part of a lithographic apparatus that is not in accordance with the present invention, but is useful for demonstrating features of the present invention. The arrangement illustrated in FIG. 4 and described below may be applied to the lithographic apparatus described above and illustrated in FIG. 1. FIG. 4 is a cross-section through a substrate support 20 and a substrate W. In an embodiment, the substrate support 20 comprises one or more conditioning channels 61 of a thermal conditioner 60, which is described in more detail below. A gap 5 exists between an edge of the substrate W and an edge of the substrate support 20. When the edge of the substrate W is being imaged or at other times such as when the substrate W first moves under the projection system PS (as described above), the immersion space 11 filled with liquid by the fluid handling structure IH (for example) will pass at least partly over the gap 5 between the edge of the substrate W and the edge of the substrate support 20. This can result in liquid from the immersion space 11 entering the gap 5.

The substrate W is held by a support body 21 (e.g. a pimple or burl table) comprising one or more burls 41 (i.e., projections from the surface). The support body 21 is an example of an object holder. Another example of an object holder is a mask holder. An under-pressure applied between the substrate W and the substrate support 20 helps ensure that the substrate W is held firmly in place. However, if immersion liquid gets between the substrate W and the support body 21 this can lead to difficulties, particularly when unloading the substrate W.

In order to deal with the immersion liquid entering that gap 5 at least one drain 10, 12 is provided at the edge of the substrate W to remove immersion liquid which enters the gap 5. In the embodiment of FIG. 4 two drains 10, 12 are illustrated though there may only be one drain or there could be more than two drains. In an embodiment, each of the drains 10, 12 is annular so that the whole periphery of the substrate W is surrounded.

A primary function of the first drain 10 (which is radially outward of the edge of the substrate W/support body 21) is to help prevent bubbles of gas from entering the immersion space 11 where the liquid of the fluid handling structure IH is present. Such bubbles may deleteriously affect the imaging of the substrate W. The first drain 10 is present to help avoid gas in the gap 5 escaping into the immersion space 11 in the fluid handling structure IH. If gas does escape into the immersion space 11, this can lead to a bubble which floats within the immersion space 11. Such a bubble, if in the path of the projection beam, may lead to an imaging error. The first drain 10 is configured to remove gas from the gap 5 between the edge of the substrate W and the edge of the recess in the substrate support 20 in which the substrate W is placed. The edge of the recess in the substrate support 20 may be defined by a cover ring 101 which is optionally separate from the support body 21 of the substrate support 20. The cover ring 101 may be shaped, in plan, as a ring and surrounds the outer edge of the substrate W. The first drain 10 extracts mostly gas and only a small amount of immersion liquid.

The second drain 12 (which is radially inward of the edge of the substrate W/support body 21) is provided to help prevent liquid which finds its way from the gap 5 to underneath the substrate W from preventing efficient release of the substrate W from the substrate table WT after imaging. The provision of the second drain 12 reduces or eliminates any problems which may occur due to liquid finding its way underneath the substrate W.

As depicted in FIG. 4, in an embodiment the lithographic apparatus comprises a first extraction channel 102 for the passage therethrough of a two phase flow. The first extraction channel 102 is formed within a block. The first and second drains 10, 12 are each provided with a respective opening 107, 117 and a respective extraction channel 102, 113. The extraction channel 102, 113 is in fluid communication with the respective opening 107, 117 through a respective passageway 103, 114.

As depicted in FIG. 4, the cover ring 101 has an upper surface. The upper surface extends circumferentially around the substrate W on the support body 21. In use of the lithographic apparatus, the fluid handling structure IH moves relative to the substrate support 20. During this relative movement, the fluid handling structure IH moves across the gap 5 between the cover ring 101 and the substrate W. In an embodiment the relative movement is caused by the substrate support 20 moving under the fluid handling structure IH. In an alternative embodiment the relative movement is caused by the fluid handling structure IH moving over the substrate support 20. In a further alternative embodiment the relative movement is provided by movement of both the substrate support 20 under the fluid handling structure IH and movement of the fluid handling structure IH over the substrate support 20. In the following description, movements of the fluid handling structure IH will be used to mean the relative movement of the fluid handling structure IH relative to the substrate support 20.

As described above, there is a first drain 10 that is configured to extract mostly gas and immersion liquid. The first drain 10 is provided to help prevent bubbles of gas from entering the immersion space 11 where the liquid of the fluid handling structure IH is present. Such bubbles may deleteriously affect the imaging of the substrate W. The first drain 10 is configured to remove both immersion liquid and gas from the gap 5 between the edge of the substrate W and the edge of the recess in the substrate support 20, WT in which the substrate W is placed. The extraction through the first drain 10 is therefore a two-phase flow. The fluid extraction through the first drain 10 may supported by a system comprising one or more pumps, flow controllers and other apparatuses. The fluid flow through the first drain 10 may be referred to as an outer extraction. The system that supports the fluid flow through the first drain 10 may be referred to as an outer extraction system.

There is also a second drain 12 that is configured to extract gas and immersion liquid that has flowed under the substrate W. The extraction through the first drain 12 may also be a two-phase flow. The fluid flow through the second drain 12 may be referred to as an inner extraction. The system that supports the fluid flow through the second drain 12 may be referred to as an inner extraction system.

The occurrence of bubbles is a particularly serious problem that may cause manufacturing defects in a number of dies. The inventors have realized that bubble occurrence is dependent on the performance of the fluid extraction, and in particular the performance of the outer extraction system. The risk of bubbles occurring may be reduced by ensuring that the outer extraction system is meeting its performance specification. If the rate of outer fluid extraction is too low, then the bubble formation may increase. If the rate of outer fluid extraction is too high, then other problems may occur, such as undesirable thermal effects.

Known techniques for determining the performance of an outer extraction system include performing a dry flow test and measuring the geometry of parts of the outer extraction system. A dry flow test comprises measuring the pressure drop that arises when only air is extracted by the outer extraction system. However, a dry flow test does not provide an accurate determination of the performance of an outer extraction system. A dry flow test uses a single phase flow (i.e. only gas) whereas the actual operation of an outer extraction system uses a two phase flow (i.e. liquid and gas). In addition, a dry flow test provides no indication of local performance, i.e. the extraction performance at a specific location on the outer extraction system.

Embodiments provide improved techniques for determining the performance of an outer extraction system. More generally, embodiments provide improved techniques for determining the performance of the fluid extraction system of a substrate support WT. The improved qualification of a fluid extraction system reduces the likelihood of bubbles occurring due to the fluid extraction system failing to meet its performance specification. This in turn improves the reliability of manufacturing processes and reduces the down time of a lithographic apparatus.

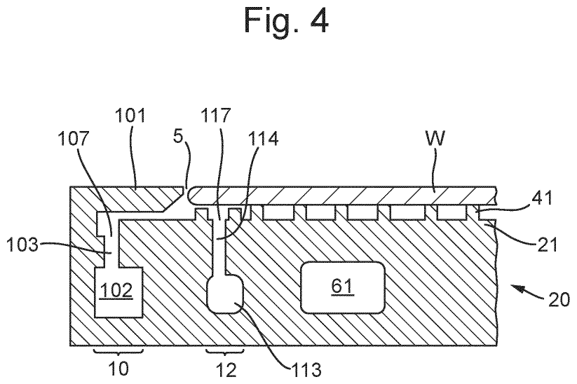

FIG. 5 schematically shows a qualification system of the fluid extraction system of a substrate support WT according to a first embodiment. The qualification system of the first embodiments may be a stand-alone tool with the specific purpose of determining the performance of fluid extraction systems of substrate supports WT.

The qualification system may comprise a qualification system support frame 502 with a receptacle of a substrate support WT. The qualification system support frame 502 is configured to support the standard operation of the fluid extraction system of the substrate support WT. The properties of the fluid extraction system are measured with a substrate W loaded on the substrate support WT. The qualification system may comprise a tool 511 for appropriately positioning a substrate W on the substrate support WT. The tool 511 may, for example, comprise shims for centering the substrate W on the substrate support WT.

The qualification system may comprise a liquid deposition system 512 arranged to deposit liquid 516 onto a major surface of the substrate W held by the substrate support WT. The liquid deposition system 512 may comprise an automatically controlled liquid supply. The fluid extraction system of the substrate support WT may be arranged to extract the deposited liquid 516.

The qualification system support frame 502 may comprise a vacuum system (not shown in FIG. 5) and conduits 501 for extracting and receiving fluid from the fluid extraction system of the substrate support WT. The received fluid by the conduits 501 may be from at least an outer extraction system of the substrate support WT. The received fluid by the conduits 501 may additionally be from an inner extraction system of the substrate support WT.

The qualification system may be arranged to measure properties of the extracted fluid from at least the outer extraction system. For this, the qualification system may further comprise one or more pressure sensors 503 arranged to measure the fluid pressure in conduit(s) 501 comprising the extracted fluid, a liquid/gas separator 505 and a flow meter 508. The liquid/gas separator 505 may receive the fluid flow from the conduits 501. The received fluid flow may comprise both liquid, e.g., the deposited liquid 516, and a gas. The liquid/gas separator 505 may separate the received fluid flow into separate liquid and gas flows. The liquid flow may flow out of the qualification system through a liquid extraction conduit 506. The gas flow may through the flow meter 508. The flow meter 508, which may be a mass flow meter 508, may measure the flow rate of the gas. The gas that has flowed through the flow meter 508 may flow out of the qualification system through a gas extraction conduit 509.

The qualification system may further comprise an open/close valve 504. The open/close valve 504 may be arranged between one of the pressure sensors 503 and the liquid/gas separator 505. The open and closed states of the valve 504 may respectively permit and prevent receiving the extracted fluid. The qualification system may also further comprise a flow adjustment valve 507. The flow adjustment valve 507 may be arranged between the liquid/gas separator 505 and the flow meter 508. The pressure of the gas may be controlled by the operation of the flow adjustment valve 507.

The qualification system may comprise a measurement system for determining operating characteristics of the fluid extraction system. The measurement system may comprise a number of different components for determining the operating characteristics. For example, the measurement system may comprise temperature sensors, pressure sensors 503, flow meters 508 and other components for determining operating characteristics.

The determined operating characteristics may include measurements the thermal characteristics of the fluid extraction. In particular, the qualification system may comprise one or more heaters 510 for heating at least part of the substrate support WT. Although not shown in FIG. 5, the qualification system may also comprise temperature sensors for measuring the temperature of at least part of the substrate support WT and/or electrical power sensors arranged to measure the power consumption of the one or more heaters 510. Measured data by the temperature sensors and/or electrical power sensors may be transmitted to a processor 514.

The determined operating characteristics may comprises a video recording of the extraction of the deposited liquid 516. In particular, the qualification system may comprise a camera 513 arranged to record a video of the extraction of the deposited liquid 516 from the major surface of the substrate W. The video recording may be transmitted to the processor 514.

The determined operating characteristics may include measurements by any component of the measurement system. All of the operating characteristics may be transmitted to the processor 514. The processor 514 may be arranged to receive operating characteristics from the temperature sensors, pressure sensors 503, flow meter 508, any other sensors, open/close valve 504, flow adjustment valve 507, any other valves, and any other components of the measurement system.

The processor 514 may generate one or more performance characteristics of the fluid extraction system in dependence of the operating characteristics. The determined performance characteristics may include a fluid extraction time and/or a fluid extraction rate. In particular, the processor 514 may determine the fluid extraction time/rate in dependence of the thermal characteristics of the fluid extraction. The processor 514 may additionally, or alternatively, determine the fluid extraction time/rate in dependence of the video recording of the fluid extraction. The processor 514 may compare the determined one or more performance characteristics with a performance specification to determine if the fluid extraction system is operating correctly. The one or more performance characteristics, and determination of correct or incorrect operation, may be presented to an operator of the qualification system on a display 515. The display 515 may be part of a computing system with processing capability, such as a laptop computer. The computing system that comprises the display 515 may additionally perform some, or all, of the tasks of the processor 514.

The processor 514 may additionally be arranged to control the operation of the qualification system.

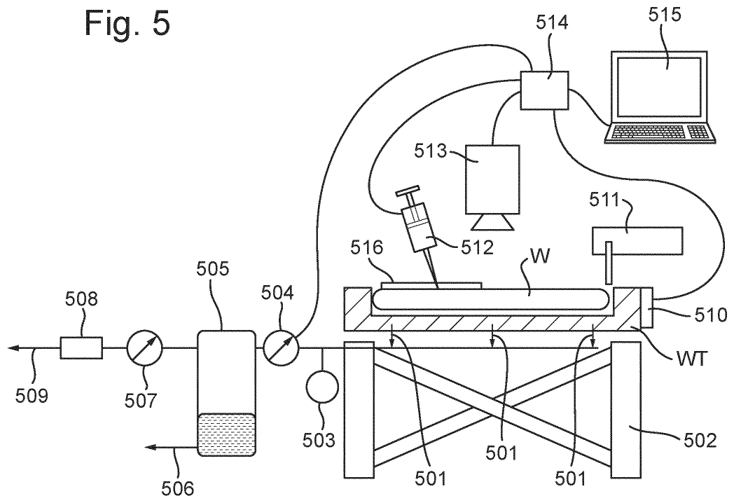

For the qualification of the fluid extraction system of the substrate support WT, a specially configured test substrate W may be used. FIG. 6 schematically shows a possible configuration of a test substrate W. The test substrate W has a major surface 601. One or more liquid confinement channels 602, that may also be referred to as rivulets, are provided on the major surface 601. There may be central liquid deposition region 604 in the middle of the of the major surface 601. One or more of the liquid confinement channels 602 may comprise deposited liquid 603. The deposited liquid 603 may be immersion fluid. The deposited liquid 603 may be deposited by the liquid deposition system 512. The deposited liquid 603 may be deposited directly into one or more of the liquid confinement channels 602. Alternatively, the deposited liquid 603 may be deposited into the central liquid deposition region 604 and then flow into the one or more liquid confinement channels 602.

Although not shown in FIG. 6, markings may be provided alongside each of the liquid confinement channels 602. The markings may be printed or written onto the major surface 601. The markings may aid the determination of the liquid flow rate when liquid flows along each liquid confinement channel 602.

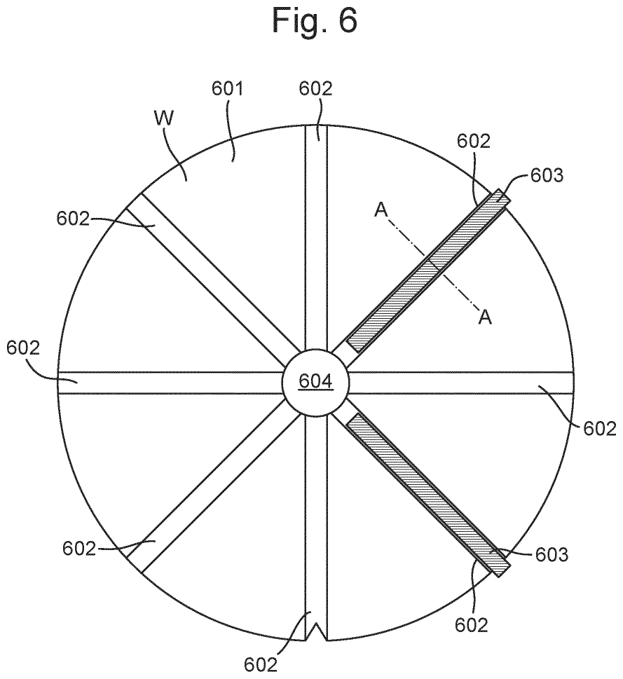

FIGS. 7A and 7B schematically show different implementations of the liquid confinement channel 602 according to embodiments. FIGS. 7A and 7B both show a cross-section through the liquid confinement channel 602, that comprises deposited liquid 603, 703, as indicated by the line A-A in FIG. 6. Although FIGS. 7A and 7B show deposited liquid 703 only touching one side of a liquid confinement channel 602, the deposited liquid 703 would typically touch both sides of the liquid confinement channel 602.

In the implementation shown in FIG. 7A, the test substrate W is coated with a layer 701 of material with a low hysteresis, such as a photoresist layer. Two channel walls 702 are formed on the layer 701. The two channel walls 702 retain the liquid 703 within the liquid confinement channel 602. Each channel wall 702 may be, for example, tape that has be directly stuck on the major surface 601 of the test substrate W.

In the implementation shown in FIG. 7B, different regions of the same surface of the test substrate W are coated with different types of materials. A first coating layer 704a may be a first type of photoresist layer. A second coating layer 704b is provided between regions of the first coating layer 704a. The second coating layer 704b may be a less hydrophobic layer than the first coating layer 704a. The second coating layer 704b may be a second type of photoresist layer. The first coating layer 704a and second coating layer 704b may comprise different materials. The boundaries between the first coating layer 704a and the second coating layer 704b define the edges of the liquid confinement channel 602. The liquid 703 is thereby confined between the boundaries.

The operation of the qualification system is described below.

A substrate support WT is loaded into the qualification system. A test substrate W, that may be dry, is then loaded onto the substrate support WT. The tool 511 may then center the test substrate W on the substrate support WT. Liquid 516, 603, 703, that may be immersion fluid, may then be deposited onto the test substrate W. The deposited liquid 516, 603, 703 is confined within the one or more of the liquid confinement channels 602, as shown in FIG. 6. The fluid extraction system of the substrate support WT may initially be switched off so that the deposited liquid 516, 603, 703 remains on the major surface 601 of the test substrate W. The one or more heaters 510 may be turned on and there may be a waiting period so that the temperature of the substrate support WT reaches a steady state.

To start the qualification process, the open/close valve 504 may be opened and the vacuum system started. The fluid extraction system then extracts the deposited liquid 516, 603, 703. The deposited liquid 516, 603, 703 flows along the one or more liquid confinement channels 602 and over the edge of the test substrate W. As shown in FIG. 6, the ends of the one or more liquid confinement channels 602 cover only parts of the circumference of the test substrate W. The fluid extraction system therefore receives a two-phase flow that is a mixture of liquid and gas.

During the fluid extraction, the measurement system of the qualification system may determine one or more operating characteristics of the fluid extraction system.

As described above, the determined operating characteristics may include measurements the thermal characteristics of the fluid extraction and/or a video recording of the extraction of the deposited liquid 516, 603, 703.

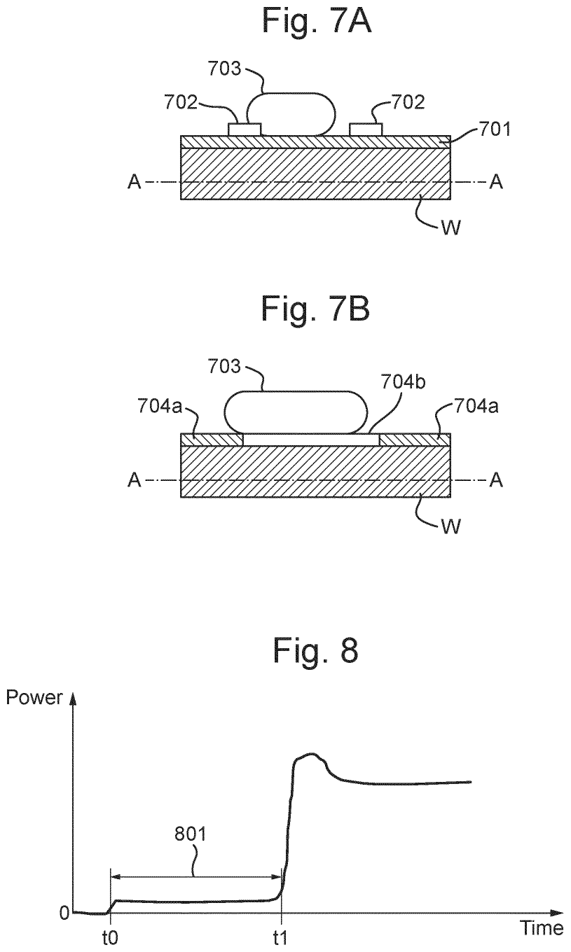

The thermal characteristics may be measured by the temperature sensors. The thermal characteristics may alternatively, or additionally, be determined by the electrical power sensors. FIG. 8 shows a hypothetical measurement result of the power consumption of the heater 510 during the qualification process. The power supply to the heater 510 may be controlled by feedback loop so that the heater 510 is operated to maintain a substantially constant temperature. Before t0, the qualification process has not started and there is either no heater power required, or the heater power is settled at a constant level (represented as ‘0’ in FIG. 8). The qualification process starts at time t0. The qualification process may be started by opening the open/close valve 504. The heater power increases due to the cooling effect of the extracted liquid and gas. The liquid flow off the major surface 601 of the test substrate W ends at time t1. The heater power is substantially constant in the time period 801 from t0 to t1. The heater power may substantially increase after t1 due to cooling effects, in particular the evaporation of residual liquid. The characteristics of the power profile in FIG. 8 may be used to determine the two phase fluid extraction properties of the fluid extraction system. For example, the time period 801 may be used to determine the liquid extraction time.

Embodiments include operating characteristics being determined in other ways and/or with other components of the qualification system. For example, the liquid extraction time and/or flow rate may be automatically, or manually, determined in dependence of measurements of the extracted gas flow rate, mass of liquid, electrodes, optical sensors, electrical connections to the test substrate W, resistive measurements of the presence of liquid, capacitive measurements of the presence of liquid, weight measurements to determine liquid presence, and by other techniques.

The processor 514 may determine one or more performance characteristics in dependence of the determined operating characteristics. For example, as described above, the processor 514 may determine the fluid extraction time in dependence on the thermal characteristics. Some of the determined operating characteristics may be used directly as performance characteristics.

The processor 514 may compare the one or more performance characteristics to a performance specification to determine if the fluid extraction system is correctly or incorrectly.

Accordingly, the above described first embodiment provides a stand-alone qualification system for determining the if the performance of a fluid extraction system of a substrate support WT meets a performance specification. Advantageously, this allows defective fluid extraction systems to be detected and the defects to be corrected. This improves the reliability of substrate supports WT and reduces the risk of bubbles occurring.

According to a second embodiment, the qualification processes are performed in a lithographic apparatus instead of a stand-alone tool.

The lithographic apparatus may have any/all of the other features or components of the lithographic apparatus as described above. For example, the lithographic apparatus may optionally comprise at least one or more of a source SO, an illumination system IL, a projection system PS, a substrate support WT, etc., Specifically, the lithographic apparatus may comprise the projection system PS configured to project the radiation beam B towards the region of the surface of a substrate W. The lithographic apparatus may further comprise the substrate support 20, WT as described in any of the above embodiments and variations.

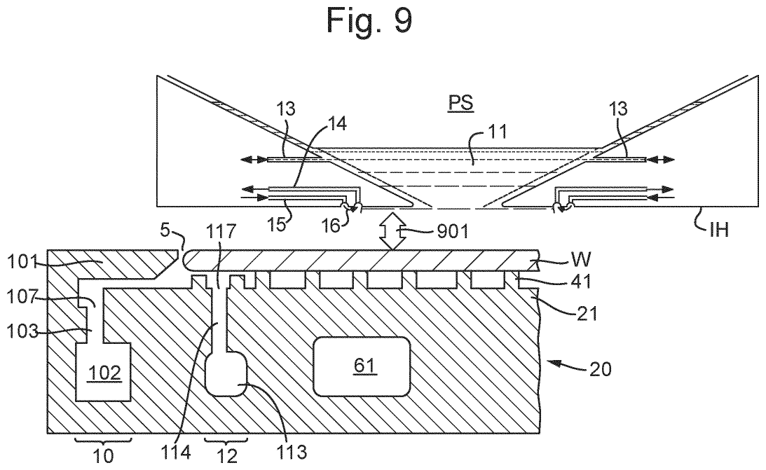

FIG. 9 schematically shows part of the lithographic apparatus. The lithographic apparatus comprises a projection system PS, with a fluid handling structure IH, that may be substantially the same as the projection system PS described earlier with reference to FIG. 2 or 3. The lithographic apparatus also comprises a substrate support 20, WT that may be substantially the same as the substrate support 20 described earlier with reference to FIG. 4. The fly height 901 is the distance between a lower surface of the fluid handling structure IH and an upper surface of a substrate W held by the substrate support 20, WT.

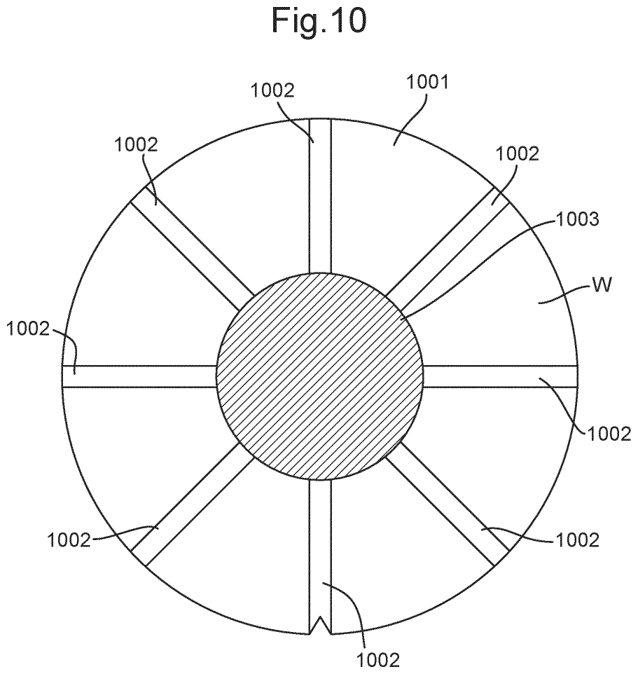

FIG. 10 schematically shows a test substrate W that may be used by the lithographic apparatus during a qualification process.

The test substrate W has a major surface 1001. One or more liquid confinement channels 1002, that may also be referred to as rivulets, are provided on the major surface 1001. There may be central liquid deposition region 1003 in the middle of the of the major surface 1001. The liquid confinement channels 1002 may confine a flow of a liquid.

The size and shape of the central liquid deposition region 1003 may be substantially the same as the opening for the flow of immersion fluid out of the fluid handling structure IH to the substrate W. Immersion fluid from the fluid handling structure IH may be deposited into the central liquid deposition region 1003. The immersion fluid may flow from the central liquid deposition region 1003 into the one or more liquid confinement channels 1002.

The one or more liquid confinement channels 1002 of the test substrate W may be provided either by channel walls or by differences in the hydrophobic properties of the surface of the test substrate W, as described earlier with reference to FIGS. 7A and 7B.

The process of performing a qualification process may comprise first loading the test substrate W, as shown in FIG. 9, into the lithographic apparatus. The projection system PS may then be positioned over the test substrate W. The fly height 901 and the flow rate of the immersion fluid may be adjusted and the central liquid deposition region 1003 filled with immersion fluid so that the liquid confinement channels 1002 are filled with immersion fluid supplied from, e.g., liquid opening 13 or supply port 72 the fluid handling structure IH, or an external source. The fluid extraction system of the substrate support 20, WT may also be operated as standard. The flow of immersion fluid and operation of the fluid extraction system may then be stopped, leaving the liquid confinement channels 1002 filled with immersion fluid. The test substrate W may then optionally be moved away from the projections system PS by a chuck swap.

The qualification process of the fluid extraction system may then be started by turning on the fluid extraction system. Only an outer fluid extraction system may be turned on, or both an outer and an inner fluid extraction system may be turned on. To determine performance characteristics, the heater power of part of the substrate support 20, WT may be monitored. In particular, by using the techniques described with reference to FIG. 8, the fluid extraction time may be determined from the variation in the required heater power. A determination of whether the substrate support 20, WT is meeting a performance specification may then be made.

According to a third embodiment, the lithographic apparatus of the second embodiment is adapted to include further devices for determining the operating characteristics.

For example, the lithographic apparatus may be adapted to comprise a camera for recording a video of the extraction of the deposited liquid 616, 603, 703 from the major surface of the test substrate W (not shown in FIG. 9). The camera may be located next to the projection system PS, or in any other location that allows it to record the fluid extraction at a location that the test substrate W may be moved to. The lithographic apparatus may also be adapted to comprise an illumination system for illuminating the major surface of the test substrate W with visible light (not shown in FIG. 9). The illumination system may, for example, comprise LEDs that may be switched on for each video recording to increase the contrast of the recorded video. As described for the second embodiment, the central liquid deposition region 1003 may be filled with immersion fluid so that the liquid confinement channels 1002 are filled with immersion fluid. The fluid extraction system of the substrate support 20, WT may also be operated as standard. The flow of immersion fluid and operation of the fluid extraction system may then be stopped, leaving the liquid confinement channels 1002 filled with immersion fluid. The test substrate W may then be moved so that the camera may record the fluid extraction. Advantageously, the measured operating characteristics may thereby include a video recording of the fluid extraction. The camera may also be used for other purposes, such as detecting contamination.

Other ways that the lithographic apparatus of the second embodiment may be adapted include using an external fluid source to deposit liquid 516, 603, 703 on the test substrate W and/or providing new fluid inlets.

Embodiments include a number of modifications and variations to the above-described techniques.

The use of an automatic liquid deposition system 512 is optional. Embodiments include liquid being deposited manually on a test substrate W by an operator of the qualification system. For example, the liquid may be deposited by a syringe.

Embodiments include many other configurations of test substrate W. For example, a test substrate with only a single liquid confinement channel 602, 1002 may be used.

On the test substrates W, the ends of the liquid confinement channels 602, 1002 provide well defined regions on their circumference in which only liquid flows over the edge of the substrate W during a fluid extraction process. The qualification test may be repeated with a different angular orientation of the test substrate W to test if the fluid extraction properties of the fluid extraction system vary around the circumference of the substrate W. The two phase fluid extraction performance of the fluid extraction system may thereby be measured locally.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Where the context allows, embodiments of the invention may be implemented in hardware, firmware, software, or any combination thereof. Embodiments of the invention may also be implemented by instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others.

Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools.

Although specific reference may have been made above to the use of embodiments of the invention in the context of optical lithography, it will be appreciated that the invention, where the context allows, is not limited to optical lithography.

Embodiments include the following numbered clauses:
1. A stand-alone qualification system for determining at least one operating characteristic of a fluid extraction system of a substrate support, the qualification system comprising:
an extraction support system configured to support a two-phase fluid extraction by the fluid extraction system; and
a measurement system configured to determine at least one operating characteristic of the fluid extraction system in dependence on the two-phase fluid extraction.
2. The qualification system according to clause 1, wherein the two-phase fluid extraction comprises a liquid flow and a gas flow.
3. The qualification system according to clause 1 or 2, wherein the substrate support is for use in an immersion lithographic apparatus.
4. The qualification system according to any preceding clause, further comprising a processor configured to determine at least one performance characteristic of the fluid extraction system in dependence on the at least one determined operating characteristic.
5. The qualification system according to clause 4, wherein the processor is configured to determine if the fluid extraction system meets a performance specification in dependence on the at least one performance characteristic.
6. The qualification system according to any preceding clause, wherein the measurement system comprises a liquid-gas separator configured to separate the two-phase flow into a gas flow and a liquid flow; and
a flowmeter for measuring the gas flow rate;
wherein a determined operating characteristic is dependent on the measured gas flow rate.
7. The qualification system according to any preceding clause, wherein the measurement system comprises one or more temperature sensors for measuring the temperature of at least part of the substrate support; and
wherein a determined operating characteristic is dependent on the measured temperature of at least part of the substrate support.
8. The qualification system according to clause 4, wherein the qualification system is configured to determine a fluid extraction rate/time; and
a determined performance characteristic is dependent on the fluid extraction rate/time.
9. The qualification system according to any preceding clause, wherein the measurement system comprises one or more cameras for recording the extraction of the fluid.
10. The qualification system according to clause 9, when dependent on clause 4, wherein the processor is configured to determine a fluid extraction rate/time in dependence on the recording; and a determined performance characteristic is dependent on the fluid extraction rate/time.
11. The qualification system according to any preceding clause, further comprising one or more heaters arranged to heat the substrate support; and
one or more electrical power sensors arranged to measure the power consumption of one or more of the heaters.
12. The qualification system according to clause 11, when dependent on clause 4, wherein the processor is configured to determine a fluid extraction rate/time in dependence on the measured power consumption; and
a determined performance characteristic is dependent on the determined fluid extraction rate/time.
13. The qualification system according to any preceding clause, further comprising a fluid deposition system;
wherein, when a substrate is held by the substrate support, the fluid deposition system is configured to deposit a liquid on the substrate.
14. The qualification system according to any preceding clause, wherein the extraction support system comprises a vacuum system for extracting the fluid.
15. The qualification system according to any preceding clause, wherein the measurement system comprises one or more pressure sensors for measuring the pressure of the fluid.
16. The qualification system according to any preceding clause, wherein at least one of the operating characteristics is locally determined for part of the fluid extraction system.
17. A substrate for use in the determination of at least one operating characteristic of a fluid extraction system of a substrate support, the substrate comprising:
one or more channels on a major surface of the substrate for containing a deposited liquid on the major surface of the substrate;
wherein each channel has an end at an edge of the substrate.
18. The substrate according to clause 17, wherein each channel is defined by a difference in the wettability properties of the major surface of the substrate.
19. The substrate according to clause 17 or 18, wherein each channel is defined by a difference in the surface profile of the major surface of the substrate.
20. An arrangement comprising:
the qualification system according to any of clauses 1 to 16; and
a substrate according to any of clauses 17 to 19.
21. An arrangement comprising:
an immersion lithographic apparatus; and
a substrate according to any of clauses 17 to 19.
22. The arrangement according to clause 21, wherein the lithographic apparatus comprises a camera arranged to record the fluid extraction.
23. A method of determining at least one operating characteristic of a fluid extraction system of a substrate support, the method comprising:
depositing liquid onto a substrate;
extracting the liquid from the substrate in a two-phase fluid flow; and determining at least one operating characteristic of the fluid extraction system in dependence on the two-phase fluid extraction.
24. The method according to clause 23, wherein the method is performed by a qualification system according to any of clauses 1 to 16.
25. The method according to clause 23, wherein the method is performed within a lithographic apparatus.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1. A stand-alone qualification system to determine at least one operating characteristic of a fluid extraction system of a substrate support prior to installation of the substrate support in a lithographic tool, the qualification system comprising:
an extraction support system configured to support a two-phase fluid extraction by the fluid extraction system; and
a measurement system configured to determine at least one operating characteristic of the fluid extraction system in dependence on the two-phase fluid extraction.

2. The qualification system according to claim 1, wherein the two-phase fluid extraction comprises a liquid flow and a gas flow, and/or wherein the lithographic tool is an immersion lithographic apparatus.

3. The qualification system according to claim 1, further comprising a processor configured to determine at least one performance characteristic of the fluid extraction system in dependence on the at least one determined operating characteristic.

4. The qualification system according to claim 3, wherein the processor is configured to determine if the fluid extraction system meets a performance specification in dependence on the at least one performance characteristic; and/or
wherein the processor is configured to determine a fluid extraction rate/time in dependence on a video recording, and a determined performance characteristic is dependent on the fluid extraction rate/time determined based on the video recording; and/or
wherein the processor is configured to determine a fluid extraction rate/time in dependence on a measured power consumption, and a determined performance characteristic is dependent on the determined fluid extraction rate/time determined based on the measured power consumption.

5. The qualification system according to claim 1, wherein the measurement system comprises a liquid-gas separator configured to separate the two-phase flow into a gas flow and a liquid flow and a flowmeter configured to measure the gas flow rate, and a determined operating characteristic is dependent on the measured gas flow rate; and/or
wherein the measurement system comprises one or more temperature sensors configured to measure the temperature of at least part of the substrate support, and a determined operating characteristic is dependent on the measured temperature of at least part of the substrate support; and/or
wherein the measurement system comprises one or more cameras configured to record the extraction of the fluid; and/or
wherein the measurement system comprises one or more pressure sensors configured to measure the pressure of the fluid.

6. The qualification system according to claim 3, wherein the qualification system is configured to determine a fluid extraction rate/time and a determined performance characteristic is dependent on the fluid extraction rate/time.

7. The qualification system according to claim 1, further comprising:
one or more heaters arranged to heat the substrate support, and one or more electrical power sensors arranged to measure the power consumption of one or more of the one or more heaters; and/or
a fluid deposition system configured to deposit a liquid on the substrate when the substrate is supported by the substrate support.

8. The qualification system according to claim 1, wherein the extraction support system comprises a vacuum system configured to extract the fluid.

9. The qualification system according to claim 1, wherein at least one of the operating characteristics is locally determined for part of the fluid extraction system.

10. A substrate for use in the determination of at least one operating characteristic of a fluid extraction system of a substrate support, the substrate comprising:
one or more channels on a major surface of the substrate for containing a deposited liquid on the major surface of the substrate,
wherein each channel has an end at an edge of the substrate, and
wherein each channel has an opposite end at a common central region of the substrate.

11. The substrate according to claim 10, wherein each channel is defined by a difference in the wettability properties of the major surface of the substrate, and/or wherein each channel is defined by a difference in the surface profile of the major surface of the substrate.

12. An arrangement comprising:
the qualification system according to claim 1; and
a substrate for use in the determination of at least one operating characteristic of a fluid extraction system of a substrate support, the substrate comprising one or more channels on a major surface of the substrate for containing a deposited liquid on the major surface of the substrate, wherein each channel has an end at an edge of the substrate.

13. An arrangement comprising:
an immersion lithographic apparatus; and
the substrate according to claim 10.

14. The arrangement according to claim 13, wherein the lithographic apparatus comprises a camera arranged to record fluid extraction.

15. A method of determining at least one operating characteristic of a fluid extraction system of a substrate support prior to installation of the substrate support in a lithographic tool, the method comprising:
depositing liquid onto a substrate;
extracting the liquid from the substrate in a two-phase fluid flow; and
determining at least one operating characteristic of the fluid extraction system in dependence on the two-phase fluid extraction.

16. The method according to claim 15, wherein the substrate comprises one or more channels on a major surface of the substrate for containing a deposited liquid on the major surface of the substrate, wherein each channel has an end at an edge of the substrate.

17. The method according to claim 15, wherein the lithographic tool is an immersion lithographic apparatus.

18. The method according to claim 15, further comprising determining at least one performance characteristic of the fluid extraction system in dependence on the at least one determined operating characteristic.

19. The method according to claim 18, further comprising determining if the fluid extraction system meets a performance specification in dependence on the at least one performance characteristic.

20. The method according to claim 15, wherein at least one of the operating characteristics is locally determined for part of the fluid extraction system.
